(19) United States
(12) Patent Application Publication
(10) Pub. No.: US 2002/0133769 A1
(43) Pub. Date: Sep. 19, 2002

(54) Circuit and method for test and repair

(76) Inventors: Timothy B. Cowles, Boise, ID (US); Christian N. Mohr, Plano, TX (US)

Correspondence Address: Charles Brantley, Micron Technology, Inc., 8000 S. Federal Way, Boise, ID, 83716, US

(21) Appl. No.: 10/022,436

(22) Filed: Dec. 12, 2001

Related U.S. Application Data
(63) Continuation-in-part of application No. 09/864,682, filed on May 24, 2001.
Application No. 09/864,682 is a continuation-in-part of application No. 09/810,366, filed on Mar. 15, 2001.

(51) Int. Cl. G11C 29/00

(52) U.S. Cl. 714/719

(57) ABSTRACT

A preferred exemplary embodiment of the current invention concerns memory testing and repair processes, wherein circuitry is provided to allow on-chip comparison of stored data and expected data. The on-chip comparison allows the tester to transmit in a parallel manner the expected data to a plurality of chips. In a preferred embodiment, at most one address—and only the column address—corresponding to a failed memory cell is stored in an on-chip address register at one time, with each earlier failed addresses being cleared from the register in favor of a subsequent failed address. Another bit—the “fail flag” bit—is stored in the address register to indicate that a failure has occurred. If the fail flag is present in a chip, that chip is repaired by electrically associating the column address with redundant memory cells rather than the original memory cells. Data concerning available redundant cells may be stored in at least one on-chip redundancy register. Additional circuitry is preferably provided to allow early switching of input signals from a first configuration directed to blow a first anti-fuse to a second configuration directed to blow a second anti-fuse, yet still allow complete blowing of the first anti-fuse. After repair, the chip's registers may be cleared and testing may continue. It is preferred that the address register and related logic circuitry be configured to avoid storing an address that is already associated with a redundant cell, even though that redundant cell has failed. In an even more preferred embodiment, testing and/or repair may occur when the chip is in the field.

### RELATED APPLICATIONS

This application is a continuation-in-part of U.S. application Ser. No. 09/864,682, filed on May 24, 2001; which is a continuation-in-part of U.S. application Ser. No. 09/810,366, filed on Mar. 15, 2001.

### TECHNICAL FIELD

The present invention relates generally to the computer memory field and, more specifically, to test and repair of memory.

### BACKGROUND OF THE INVENTION

A memory device is often produced using a semiconductor fabrication process. In the current application, the term “semiconductor” will be understood to mean any semiconductor material, including but not limited to bulk semiconductive materials (either alone or in assemblies comprising other materials thereon), and semiconductive material layers (either alone or in assemblies comprising other materials). Moreover, it shall be understood that a semiconductor device may comprise conductive and insulative materials as well as a semiconductive material. The result of a semiconductor process may be a die comprising memory circuitry, and it may be desirable to test that circuitry at some point during the process of constructing a memory device comprising that die. For instance, testing may occur while the die is part of a semiconductor wafer, after singulation from the wafer, during die packaging, or once the memory device (chip) is completed.

One conventional method of testing such a chip is to have an external testing device write data to every memory cell of the chip, then read data from every memory cell, and compare the input with the output. Such a comparison may reveal cells that failed to store the data properly. The addresses corresponding to these defective cells can be stored by the external testing device, and that stored data may be used to repair the chip. In order to effect such repair, redundant cells are provided on the chip, as well as at least one bank of programmable elements, such as fuses or anti-fuses, that controls access to the redundant cells. Assuming the bank to be comprised of anti-fuses, repair circuitry receives each address corresponding to a defective cell and, based on that address, blows at least one anti-fuse, thereby isolating the defective cell and associating the address with a redundant cell.

This error detect and repair scheme, however, raises issues. One such issue is the number of chips that may be tested at one time. A typical testing device is an AMBYX machine. The AMBYX can hold 256 chips and may electrically connect to all of them. Hence, the AMBYX can write to all chips in parallel. However, the AMBYX cannot read potentially differing data from all 256 chip in parallel. Rather, it has limited resources concerning reading data from the chips. Specifically, the AMBYX has only 64 terminals (known as “DQ's”) for reading from the chips. As a result, the 256 chips must share these DQ resources. Assuming each chip has only four DQ's of its own (in which case the chips would be known as a “x4” part), then the AMBYX could access only 16 chips at one time. Thus a typical testing process would involve writing data to cells of 16 chips; reading data from cells of all 16 chips; comparing the written data with the read data; and, for cells wherein the written data and read data do not match, storing the addresses of those failed cells. These steps must be performed 15 more times in order to test all 256 chips on the AMBYX. Moreover, once repaired, the chips are often retested in a second test cycle to determine whether the repair was successful, thereby requiring even more time, especially if the chips must be removed from the AMBYX for repair and then placed back onto the AMBYX for retesting. Further, more than one type of test is often conducted. As a result, there is a desire in the art to shorten test time.

Still other issues include the time and circuitry used to repair the chips. First, as mentioned above, the machine used to repair the chips may be different from the machine used to test the chips. Thus, it is often the case that the chips must be removed from the AMBYX and placed in another device, such as one made by TERADYNE, thereby undesirably adding time and effort. Further, maintaining the assumption (only for purposes of example) that completely packaged parts are being repaired, it can be understood that at least some of the redundant elements provided on a chip's die may have been used as a result of prior testing and repair processes, possibly including those accomplished at some stage prior to complete packaging. Thus, in repairing packaged parts, a testing or repair device may examine the chips to determine whether there are still redundant elements available for repair. If there are, the location of the elements is stored in registers within the testing device, and repair commences. Repair often involves transmitting in parallel the first address to the address inputs of one chip, transmitting a command to blow an anti-fuse on each chip that would reroute signals pertinent to that address to a redundant cell, and transmitting through the DQ lines a command to ignore the blow command if the first address does not match a failed address stored within the repair device's registers. This process is subsequently performed for the chip's second address, then the third address, etc., until all of the addresses have been accommodated. Then the process is repeated for the next chip. The serial nature of this repair scheme is very time consuming, and, as with the testing process, there is a desire in the art to reduce the time used for repair. Built In Self Repair (BISR) techniques may be used to affect test time, but often this is accomplished at the cost of the amount of die size needed to allot to on-chip registers and repair logic.

Moreover, neither alternative addresses the timing for the signals needed to blow the anti-fuses. In prior art, the appropriate signals must be transmitted to the chips for a certain amount of time to ensure that the anti-fuses will blow. Once that time has elapsed, the signals are changed to accommodate the next address. It is desirable to shorten repair time, but early reconfiguration of the signals to accommodate the next address risks an incomplete blow of the first anti-fuse and thereby may result in a failure to repair the chip. As a result, there is a need in the art for repair circuitry and methods that affect the time required to repair the chips while avoiding a great increase in die size and avoiding a great risk of an incomplete repair.

### SUMMARY OF THE INVENTION

Accordingly, exemplary embodiments of the current invention provide methods and circuitry for testing and repairing a chip. In one exemplary embodiment, data stored on a chip's memory is read to the extent that it is accessed from the memory array. However, rather than transmit the data to an external testing device, the chip's output circuitry is tri-stated, the external testing device transmits to the chip the data that is expected to be stored, and a comparison between the stored data and the expect data occurs on chip.

Another embodiment concerns storing a result of a test in an on-chip address register, regardless of whether that test is one described above or another. In a preferred embodiment, at most one failed address is stored, along with a bit indicating that a failure has been found. In a more preferred embodiment, the stored address is the last failed address resulting from the test; and only the column address, rather than both the column and row address, is stored. In another embodiment, the address register of a failed part is cleared after testing, and further testing commences. If such testing reveals a failed address already associated with a redundant cell, that address is not stored, although a bit indicating that a failure has been found is stored.

In yet another embodiment, chip repair is carried out wherein, given a defective memory cell, an entire group of memory cells including the defective cell is replaced by a redundant group of cells. In a preferred embodiment of this type, an entire column of redundant memory cells replaces a column of memory cells containing the defective cell. In a more preferred embodiment, the address of the defective memory cell is stored in an on-chip register. In an even more preferred embodiment, only one column—the column including the last recorded failed memory cell—is replaced as a result of one test cycle. In many embodiments, the location of available redundant cells that will allow replacing the entire column is stored in at least one on-chip redundancy register. Preferably, the redundancy register stores only a column address corresponding to an available redundant column of cells. Still more preferably, the redundancy register stores only a column address corresponding to the available redundant column of cells found last in a search, discarding earlier column addresses for later-found ones.

Still other embodiments allow signals having a first configuration directed to blowing a first anti-fuse to be switched to a second configuration directed to blowing a second anti-fuse, wherein the switch is performed before the time sufficient to blow the first anti-fuse. Nevertheless, the relevant signal is still transmitted to the circuitry of the first anti-fuse for a time sufficient for blowing. In a preferred embodiment, this is accomplished by making the effect of changes in an input signal synchronous with a modified clock signal. In a preferred embodiment of this type, the signals that blow anti-fuses allow for chip repair as summarized above

These and other embodiments within the scope of the invention include within the scope both apparatuses and methods; and still other embodiments encompass combinations of the embodiments listed above. Also included are embodiments concerning methods and devices relating to test and/or repair of memory in the field.

### BRIEF DESCRIPTION OF THE DRAWINGS

FIG. 1 depicts a prior art testing device for a plurality of chips.

FIG. 2 is a table comparing a test method known in the art with an exemplary method within the scope of the current invention.

FIG. 3 illustrates circuitry of an exemplary apparatus embodiment within the scope of the current invention.

FIG. 4 is a table comparing a second test method known in the art with a second exemplary method within the scope of the current invention.

FIG. 5 is a table comparing a third test method known in the art with a third exemplary method within the scope of the current invention.

FIG. 6 illustrates prior art circuitry.

FIG. 7 is a chart illustrating hypothetical memory chip test results.

FIGS. 8A and 8B are tables comparing a prior art repair method with an exemplary repair method within the scope of the current invention.

FIGS. 9A and 9B depict portions of circuitry addressed by exemplary embodiments of the current invention.

FIG. 10 illustrates another portion of circuitry addressed by an exemplary embodiment of the current invention.

FIGS. 11A-C show timing diagrams illustrating command sequences and effects thereof in the prior art.

FIG. 12 depicts a portion of circuitry addressed by an exemplary embodiment of the current invention.

FIGS. 13A and B depict portions of circuitry addressed by exemplary embodiments of the current invention.

FIG. 14 shows a timing diagram illustrating a command sequence and effects thereof as part of an exemplary embodiment of the current invention.

FIG. 15 depicts another exemplary apparatus embodiment within the scope of the current invention.

FIG. 16A depicts a cross-section of a single die package within the scope of the current invention.

FIG. 16B depicts a top-down view of a multi-chip module within the scope of the current invention.

FIG. 17 depicts a desktop computer system within the scope of the current invention.

FIG. 18 depicts a laptop computer system within the scope of the current invention.

FIG. 19 depicts a cellular phone system within the scope of the current invention.

FIG. 20 depicts a computer system within the scope of the current invention.

FIG. 21 depicts a motherboard within the scope of the current invention.

FIG. 22 depicts a module within the scope of the current invention.

### DETAILED DESCRIPTION OF THE PREFERRED EMBODIMENTS

Exemplary embodiments of the current invention address methods and circuitry for detecting errors, repairing errors, or both.

I. Error Detection

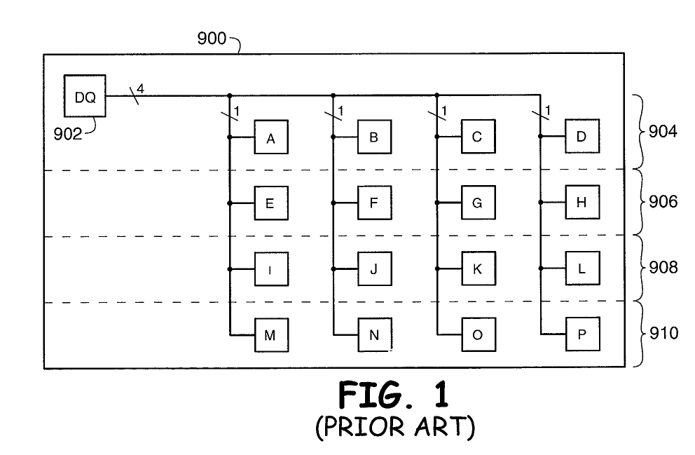

In terms of error detection, exemplary embodiments of the current invention shorten test time by presenting a testing scheme alternative to the one presented in the Background. To begin with, a simplified test method practiced in the prior art is presented. FIG. 1 presents a portion of a simplified tester 900 having only four DQ's 902. While the tester 900 may be able to physically hold 16 chips (A-P), its circuitry is designed to receive signals from at most four chips at one time. It is understood that the tester 900 also has conductive lines (not shown) that carry address and command information to the chips, and that these lines are also limited in number and so can receive signals from at most four chips at a time. The areas in which the tester may communicate in such a fashion are identified in this specification as “regions.” Tester 900 has four regions 904, 906, 908, and 910. Further, it is assumed for purposes of explanation that the parts A-P are “x1” parts (each having only one DQ) and have only four memory addresses.

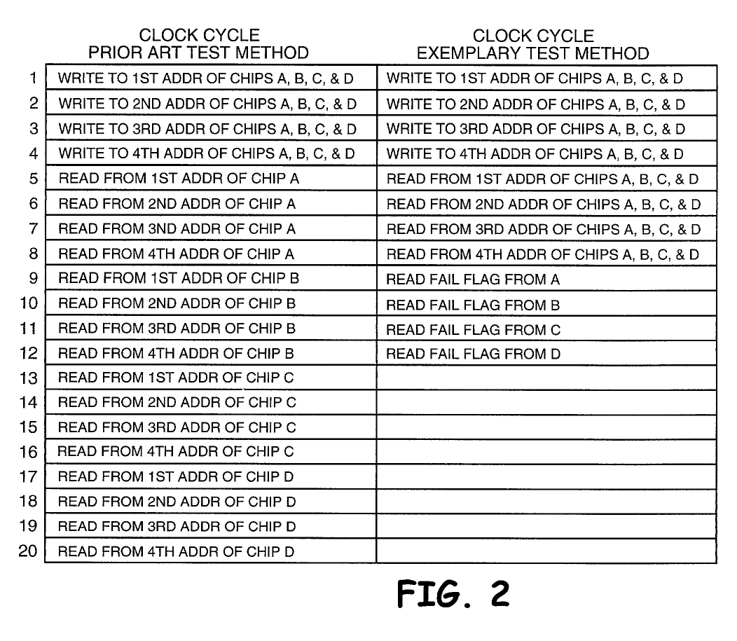

The prior art commands for one exemplary test using tester 900 are depicted in the left-hand column of the table in FIG. 2. During the first clock cycle, the same bit is written to a cell corresponding to the first address in each of chips A-D. Because the same bit is being written, the write step may occur in parallel with respect to chips A-D. Similar parallel writing steps may be taken to write to the second, third, and fourth addresses of chips A-D. As a result, writing to every address of all four chips requires 4 clock cycles. However, reading from the chips A-D for purposes of off-chip comparison with expected data may not be performed in parallel, as the chips may not output identical data due to chip failures which this test seeks to reveal. As a result, the tester must read from each address in each chip in series. FIG. 2 indicates that reading from all four addresses of chip A requires four clock cycles (5-8). In fact, four clock cycles are required to read from all addresses of each chip, resulting in a total of twenty clock cycles needed to test the four chips 20 in this one region 904 of the tester 900. An additional 20 clock cycles is then needed for each of the remaining regions 906, 908, 910. Thus in this example, test time takes 80 clock cycles, and that amount is just for one test. Generally several tests are performed on the chips, with each test requiring 80 clock cycles. Moreover, chips that failed a test the first time often repeat that test after being repaired, thereby requiring even more test time. One can now appreciate the degree to which the required test time can multiply.

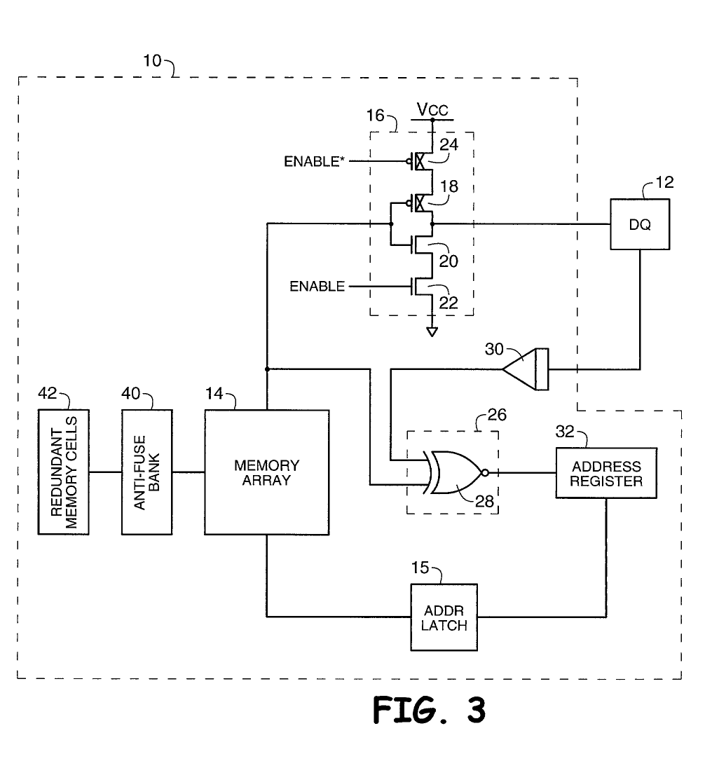

At least one exemplary embodiment of the current invention affects the time required to perform such a test. Such an embodiment is depicted in FIG. 3, which illustrates circuitry included as part of a chip 10, and a DQ 12 of a tester. Chip 10 includes a memory array 14 comprising main or primary memory cells; an address latch 15 that is configured to transmit a memory address (and may further comprise a separate row address latch and column address latch); an anti-fuse bank 40 which, based on its programming state, may divert a signal for a cell in the memory array to one in a bank of redundant memory cells 42; and output circuitry 16. The output circuitry 16 is connected to the memory array 14 and the DQ 12. Output circuitry 16 comprises four transistors 18, 20, 22, and 24. The gates of p-channel transistor 18 and n-channel transistor 20 are connected to each other and to the memory array 14. Their drains are also connected to each other and to DQ 12. N-channel transistor 22 is coupled to ground and to transistor 20 and is driven by a signal ENABLE. A complementary signal ENABLE* drives transistor 24, which is coupled to a voltage source Vcc and to transistor 18.

In a standard read operation, the ENABLE signal represents a high voltage signal that turns on transistor 22. Accordingly, the ENABLE* signal represents a low voltage signal that turns on transistor 24. A data value from at least one cell in memory array 14 (designated by the address in the address latch 15) is transmitted to the gates of transistors 18 and 20, and an inverted signal is output from their drains to the DQ 12. However, in a test mode under an exemplary embodiment of the current invention, ENABLE is at low voltage. As a result, transistor 22 turns off (isolating the output circuitry 16 from ground), ENABLE* is at a high voltage, and transistor 24 turns off (isolating the output circuitry 16 from Vcc). The state of the output circuitry 16 in this mode is known as a “tri-state.” The data value from memory cell 14 nevertheless transmits to an on-chip comparison circuit 26, which, in this example, is an exclusive NOR gate 28 that receives both the data from the memory array 14 and the data transmitted from the tester's DQ 12 (it is preferred, although not required, that the signal from DQ 12 first pass through an input buffer 30). Although the output circuitry 16 has been tri-stated and data is being transmitted to the chip 10 through the DQ 12, the chip 10 is considered to be in a “read” mode given that the data stored on chip 10 is being accessed. Based on the truth table for an EXCLUSIVE NOR operation, the EXCLUSIVE NOR gate 28 will output a low voltage signal only when both inputs fail to match, thereby indicating a defect in the cell corresponding to the memory address. The low voltage output from the EXCLUSIVE NOR gate prompts a storage device such as address register 32 to store the memory address transmitted by the address latch 15. Moreover, it is also preferable (although not required) for purposes of further testing as discussed below that the address register 32 also store a bit that indicates whether an error has been found. For purposes of explaining other exemplary embodiments of the current invention, this bit will be referred to as the “fail flag.”

The right column of FIG. 2 illustrates that using the circuitry described above allows for an exemplary method of testing chips A-P on FIG. 1's tester 900 with fewer steps than was used in the prior art. As in the prior art, a particular bit may be written to every chip in a region in a parallel manner. Thus, writing to the first address of chips A-D can be performed in the same clock cycle, as can writing to the second, third, and fourth addresses. While writing to chips A-D takes the same number of clock cycles as in the prior art, the savings in this exemplary testing method appear when the chips enter their “read” mode.

Unlike the prior art test, the tester's DQ's 902 are not needed to serially transmit possibly differing data from chips A-D. This is because analysis of the chips' stored data occurs within each chip. Thus, the tester's DQ's 902 may now be used to transmit to chips A-D the data that is expected to be stored in the first address on those chips. Because the data written to the first address is the same for chips AD, the expected data is also the same, and that expected data may be therefore transmitted by the tester in a parallel fashion. As a result, only one clock cycle is used to test the first address in chips A-D. A mismatch between the expected data and the data read from the first address of any of the chips A-D suggests a defective memory cell. In that event, the first address of the relevant chip would be stored in its address register 32 along with data—such as the fail flag—indicating that at least one error has been found on that chip.

Subsequently, the second address of chips A-D is read during the next clock cycle and compared with the expected data, and so on for the third and fourth addresses, with the failed addresses being stored in the appropriate address register 32 accordingly. As a result, this exemplary testing method accomplishes in eight clock cycles what it took the prior art twenty clock cycles to accomplish. Even after adding the preferred steps of serially reading for the fail flag that could result from the on-chip comparisons, clock cycle savings are still realized in comparison to the prior art method. It is further preferred that the circuit in FIG. 3 and process of FIG. 2 be implemented with chips that exhibit a latency of 1 or 2, wherein latency indicates the delay in the number of clock cycles between the arrival of a “read” command and the availability of data to be read. Nevertheless, it should be understood that the current invention includes within its scope exemplary embodiments implemented with chips that exhibit other latencies and that include any extra logic circuitry to accommodate those latencies.

Moreover, it should be remembered that the example is a relatively simple one, with each chip having only four addresses and the tester 900 being able to test only four chips at once. As discussed in the background section, it is not unusual to test chips having millions of addresses per chip and to test them sixteen at a time. The savings offered by the exemplary method embodiment disclosed above become even greater with added complexity of the test scheme.

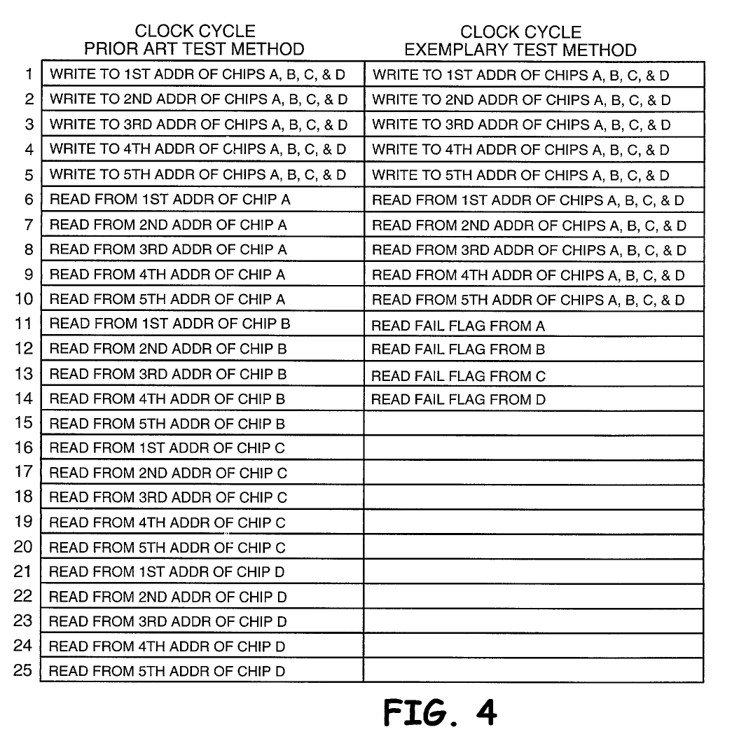

For instance, assuming that chips A-P had five addresses rather than four, the table in FIG. 4 illustrates that the prior art test of region 904 would require five additional clock cycles: one clock cycle for a parallel write command to the fifth address of chips A-D; and four clock cycles, each needed to read from the fifth address of each chip A-D. In contrast, the exemplary method could use only two additional clock cycles: one clock cycle for a parallel write command and one clock cycle for a parallel read command.

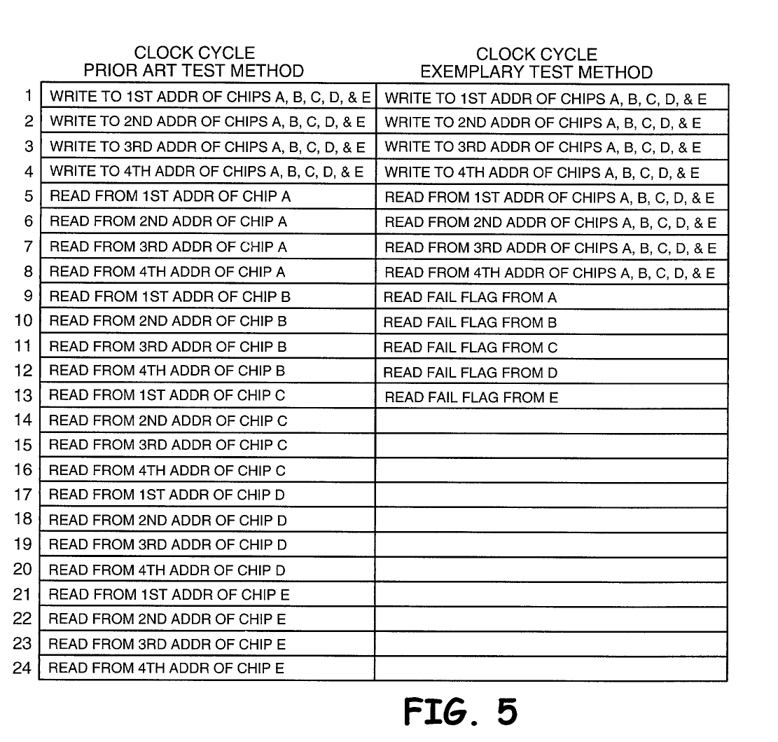

Another example illustrated in the table of FIG. 5 assumes that five chips (each having four addresses) could be tested in parallel rather than four chips. The prior art method would require four more clock cycles to read from the four addresses of that extra part, whereas the exemplary method would require only one extra clock cycle to read the fail flag from the extra part; reading from all addresses of chip E requires no additional clock cycles, as that can be performed in the same clock cycle for reading from the other chips.

As a result, one can now appreciate that an increase in the chips per region, the number of regions, the number of tests, or the number of bits per chip results in a multiplied amount of clock cycle savings during testing using exemplary embodiments of the current invention. Such savings can result in shorter test time or allow more time for other tests. In fact, testing directed by the inventor using exemplary embodiments of the current invention has demonstrated a reduction in test time by 45%.

The preferred number of failed address to be stored in address register 32 can be based on balancing the desire to fabricate as small a chip as possible with the desire to increase the likelihood of being able to keep track of all addresses corresponding to defective cells after one test cycle. The greater amount of on-chip test circuitry (including a large register capable of storing many failed addresses and the supporting logic circuitry), the more likely it is to ensure such ability. The cost, however, is that a great amount of die space may be devoted to that. Conversely, a lesser amount of on-chip test circuitry (including a register capable of storing few failed addresses and less supporting logic circuitry) allows for less die space to be devoted at the cost of some ability to keep track of all failed addresses after one test cycle. Such a balancing has been made concerning Synchronous Dynamic Random Access Memory (SDRAM) parts recently fabricated by Micron Technology, Inc., including part numbers MT48LC32M4A2 (an 8 Meg×4×4 bank part), MT48LC16M8A2 (a 4 Meg×8×4 bank part), MT48LC8M16A2 (a 2 Meg×16×4 bank part), and MT48LC4M32B2 (a 1 Meg×32×4 bank part). These parts incorporate many of the exemplary embodiments of the current invention. An analysis of the failed cells found on these parts during testing revealed that 90% of the failed chips can be fully repaired by replacing only one column containing at least one defective cell with a redundant column. As a result, these parts have a register that stores only a single failed address at one time (preferably in addition to the fail flag), and that address is only the column address, without the row address. Accordingly, a relatively small failed address register and related logic circuitry is provided on-chip. Further, it is preferred that the register store the latest failed address, clearing any former address that may have been stored.

After the test, the chips containing defective cells may be repaired. Such chips will be identified by the presence of the fail flag value in the address register 32 of relevant chips. Chips without the fail flag may bypass the repair process, thereby allowing the limited resources of the repair device to be devoted to the chips that need repair.

Once the chips have been repaired, they may undergo a repeat of the previous test. Alternatively, they and the chips that passed the previous test may be subjected to a different test. In such cases, the address and fail-flag value may be cleared from the repaired chips' address registers 32 before testing continues, and the testing process proceeds as described above. Further testing may reveal a defect concerning an address wherein the originally associated column of cells has already been isolated in favor of a redundant column as a result of a prior repair. In some exemplary embodiments of the current invention, it is not desirable to include circuitry designed to isolate a one redundant column in favor of a second. Thus, although not required in every embodiment of the current invention, it is preferable in certain exemplary embodiments to avoid storing a failed address in address register 32 if that address is already associated with a redundant cell. The status of the anti-fuses in the anti-fuse bank 40 can be used to determine if such is the case. If such a failure occurs, however, it is desirable to record the existence of the failure by storing the fail flag in address register 32. Thus, if at the end of a test, the address register 32 stores a fail flag with no address, that is an indication that a redundant cell has failed, and the chip may be handled accordingly.

II. Error Repair

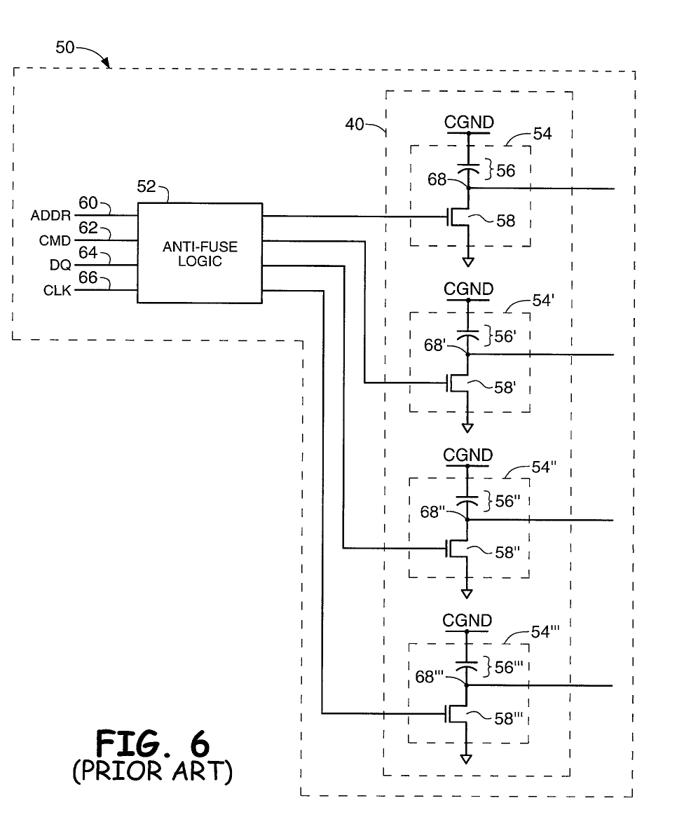

In terms of error repair, exemplary embodiments of the current invention present repair schemes alternative to the ones disclosed in the prior art. In the prior art, for instance, repair may occur by placing the chips in a repair device, such as a TERADYNE machine, wherein the TERADYNE has stored within its registers the failed addresses as well as the location of available redundant elements of each chip. Repairing is then performed on a plurality of chips such as the chip 50 depicted in FIG. 6. On that chip 50, anti-fuse logic 52 is coupled to an anti-fuse bank 40 comprising anti-fuse circuits such as anti-fuse circuits 54, 54′, 54″ and 54′″. Anti-fuse circuit 54 comprises a capacitor (the anti-fuse 56) having one plate coupled to a voltage CGND (which may also be known as Vpop, and in this example is 9 volts), while the opposing plate is coupled to ground through transistor 58. Transistor 58 is driven by a signal from anti-fuse logic 52. Anti-fuse circuits 54′, 54″, and 54′″ are configured similarly, but their analogous transistors may be driven by unique signals from the anti-fuse logic 52. The driving signals from the anti-fuse logic 52 are, in turn, determined by the control signals input from the TERADYNE. The address input ADDR 60 determines which address may be isolated from its original memory cell and associated with a redundant cell. The CMD input 62 carries the command to chip 50 to blow an anti-fuse. The state of the DQ input 64 determines whether a particular chip will ignore the CMD input 62. These signals are logically related by anti-fuse logic 52 to determine whether transistor 58 and/or its analogs in other anti-fuse circuits 54′, 54″, etc., are to be driven. The anti-fuse logic also receives a clock input CLK 66, which may be a pulsed signal transmitted at a regular interval or period. Changes in the address input ADDR 60 and DQ input 64 result in a change of output signals that determine which if any of the anti-fuse circuits 54, 54′, 54″, or 54′″ are driven.

Before transistor 58 is driven, the insulation between the electrodes of anti-fuse 56 blocks a conductive path from CGND to node 68. Once transistor 58 is driven, the voltage difference between CGND and ground begins to break down the dielectric of anti-fuse 56. If transistor 58 is driven for 2 milliseconds, then the dielectric breaks down sufficiently enough to form a permanent conductive path between CGND and node 68, and the anti-fuse 56 is considered blown. Once anti-fuse logic 52 stops driving transistor 58, then node 68 is isolated from ground, and CGND may affect other circuitry coupled to node 68 such that a particular address may become associated with a redundant memory cell and isolated from a main memory cell.

The information concerning available redundant elements on each chip results from checking the status of the anti-fuses used to access them. Thus, circuitry connected to node 68 could be used to determine whether the voltage source CGND is still isolated from node 68. If such isolation exists, then capacitor 136 has not been blown, and the fact that the related redundant cell remains available is recorded by the repair device. Analogous to cells in the main memory array 14, cells in the redundant memory array 42 have their own row and column addresses, and one method of storing the fact that a related redundant cell remains available is to store its redundant row and column address. Prior art teaches repeating this procedure for each redundant element.

It is assumed that blowing anti-fuse 56 of circuit 54 of any of the chips A-D would reroute a signal related to the first address from a main memory cell to a redundant memory cell. It is also assumed that blowing the anti-fuse 56′ of circuit 54′ would reroute a signal related to the second address of any of the chips A-D. For chip A, it is further assumed that the anti-fuse 56 remains unblown; and the availability of anti-fuse 56 for repair of chip A is stored on the repair device. For chip B, it is assumed that the anti-fuse 56′ is configured to repair the second address and remains unblown. The availability of anti-fuse 56′ for repair of chip B is also stored on the repair device.

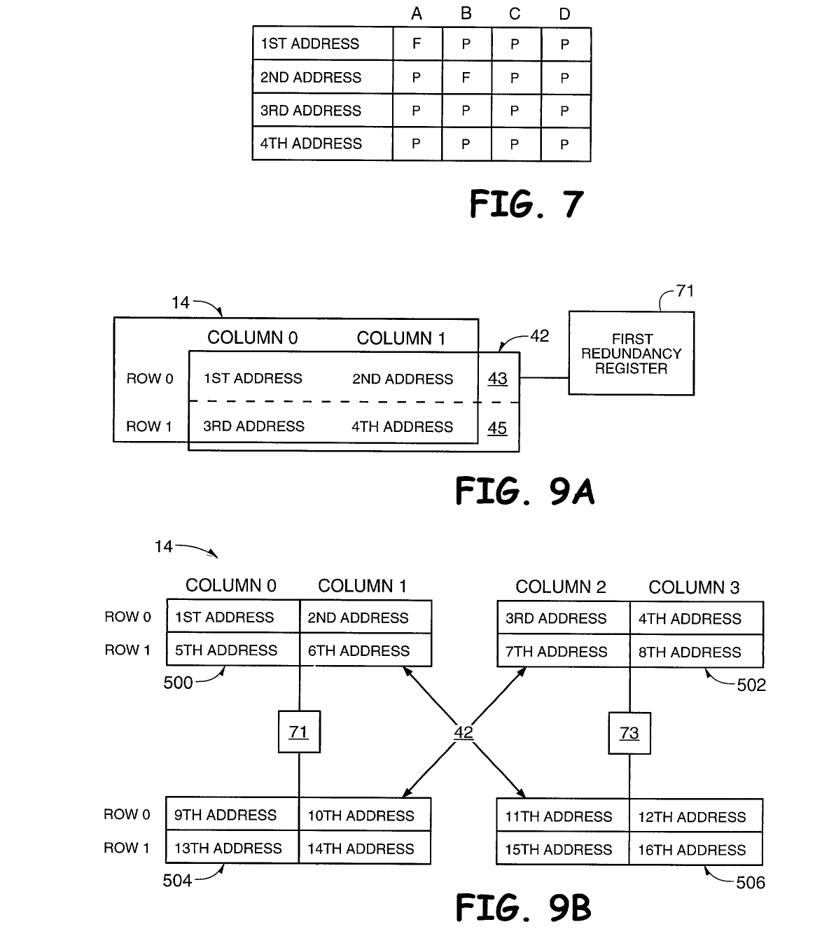

In repairing four chips A-D (each with four addresses, a single DQ, and a configuration such as that of chip 50 in FIG. 6), the assumed test results for purposes of explanation are illustrated in FIG. 7. Specifically, it is assumed that the memory cell corresponding to the first address of chip A failed testing (indicated by the “F”), with the three cells corresponding to chip A's other three addresses passing the test (indicated by the “P”). Chip B, on the other hand, was found to have a defective cell corresponding to the second address, while the cells corresponding to the first, third and fourth addresses passed. All cells of chips C and D passed.

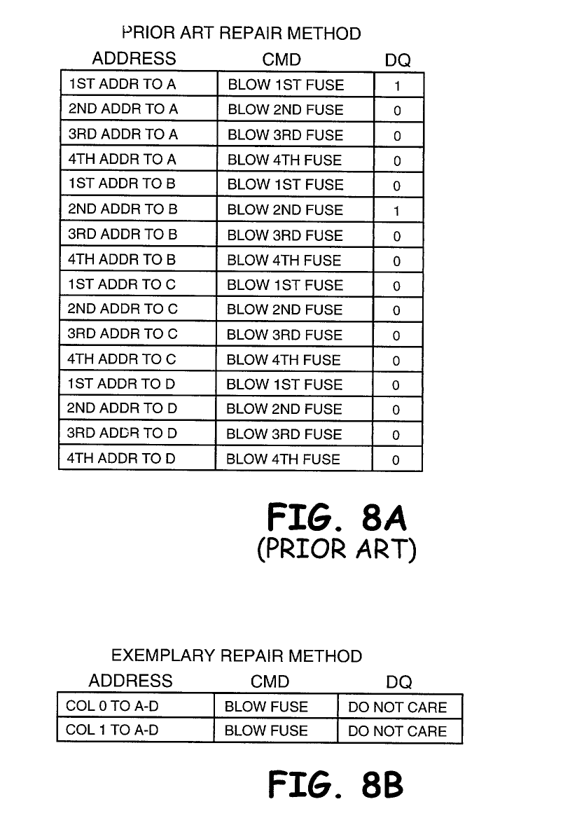

As a result, when prior art repair techniques begin, the TERADYNE transmits the instructions illustrated in the table of FIG. 8A. The table in FIG. 8A indicates that instructions may be transmitted to at least the address input ADDR 60, the command input CMD 62, and the DQ input 64 illustrated in the circuitry of FIG. 6. The first set of instructions includes (1) the first address, which is transmitted through the address input ADDR 60 to chip A; (2) the command to blow the anti-fuse associated with the first address, which is transmitted along the CMD 62 input; and (3) the instruction to allow the blow anti-fuse command, which is transmitted by a high voltage signal through the DQ line 64 to chip A. Once these commands are present for the required amount of time, anti-fuse 56 of chip A will blow, thereby associating the first address with a redundant cell. The next set of instructions are directed to the second address of chip A. Hence, the second address is transmitted through the address input ADDR 60 to chip A; the command to blow the fuse associated with the second address is transmitted along the CMD 62 input; but, because the cell corresponding to the second address passed its test, an instruction to ignore the blow fuse command is transmitted by a low voltage signal through the DQ input 64 to chip A. Transmissions of analogous instructions concerning the other addresses of chip A, as well as the addresses of chips B-D, follow in series.

At least some of the exemplary embodiments of the current invention provide alternative repair circuits and methods. Methods and circuits concerning the number and relationship of elements used in repair and/or recording the availability of redundant elements are addressed under the heading of “Smart Repair.” Methods and circuits concerning the timing of signals transmitted during repair are addressed under the topic of “Speedy Repair.”

A. Smart Repair

Preferred embodiments of the current invention concerning the number and relationship of elements used in repair and/or recording the availability of redundant elements (1) involve aspects related to the notion of redundant planes; and (2) are used in conjunction with embodiments concerning error detection described in part I above.

Concerning redundant planes, it should be noted that redundant elements of a memory chip may be organized into at least one redundant plane, in addition to being organized by redundant row and column addresses. Each redundant plane may be configured to accommodate a particular portion of the total main memory. If there is only one redundant plane for a memory array, it follows that any of the plane's redundant elements is configured to replace any cell in the memory array. Doing so can involve an undesirable amount of support circuitry, however. As a result, there are often a plurality of planes devoted to the totality of the main memory cells, wherein each plane may be configured to accommodate a discrete portion of the total main memory. Returning to the example wherein chips having only four addresses are repaired, it is further assumed that the architecture of memory array 14 is like that illustrated in FIG. 9A. Specifically, the memory array 14 is arranged into two columns (column 0 and column 1) and two rows (row 0 and row 1), wherein the first address and the third address are in the same column, and the second and fourth addresses also have a common column address. It is further assumed that the array of redundant memory cells 42 is divided into two planes, wherein redundant cells of the first plane 43 are configured to accommodate only the first or second addresses, and redundant cells of the second plane 45 are configured to accommodate only the third and fourth addresses. It is also noteworthy that multiple redundant planes are used to accommodate the entirety of a particular column. It is also noteworthy that redundant cells having a common redundant column address may be organized into different planes.

Regarding embodiments concerning error detection, it should be remembered that, in preferred embodiments of that type, an on-chip address register 32 is provided and configured to store the column portion (and not the row portion) of the main memory address of the last failed cell found, as well as a fail flag. This is done because it is preferred to replace an entire column's-worth of cells. Hence, in preparation for repair, it is desired to identify a column's-worth of redundant cells in the redundant array. It is even more preferable to identify a group of available redundant cells sharing the same column address in the redundant array. If such a redundant column is found, one may store only the column address of the redundant column rather than storing the redundant row addresses as well. Such storage is preferably accomplished with a storage device such as a redundancy register 71 (FIG. 9A). In a manner analogous to the preferred operation of the address register 32, the redundancy register 71 stores only one redundant column address, with an earlier-found redundant column address being cleared from the register in favor of a later-found redundant column address. In an even more preferable embodiment, the redundancy register is on chip.

Moreover, if the redundancy register stores data pertinent to an entire column of redundant cells, and the entire column of redundant cells is split between a plurality of redundant planes, it follows that one redundancy register may contain data relevant to more than one redundant plane. Thus, in the exemplary circuitry of FIG. 9A, there is a first redundancy register 71 configured to store a redundant column address that may be relevant to at least one cell in redundant plane 43 and at least one cell in redundant plane 44.

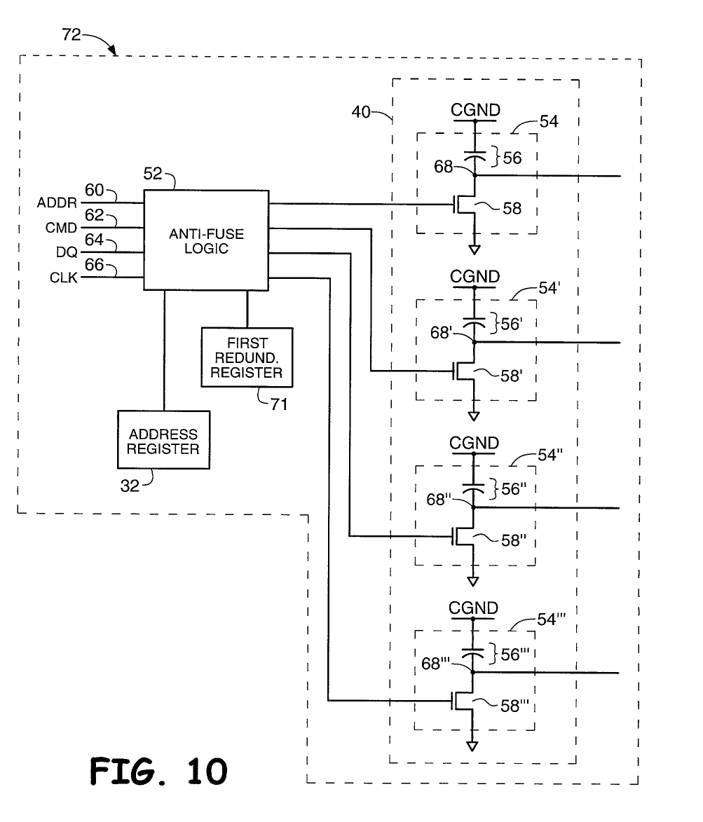

An illustration of the preferred “Smart Repair” embodiment combined with a preferred error detect embodiment is illustrated in FIG. 10, wherein the circuitry forming part of chip 72 includes address register 32, which is preferably configured to store the column address of the last failed cell found during the preceding test (and a fail flag bit if such a failure is found). The circuitry forming part of chip 72 also includes the first redundancy register 71. The first redundancy register 71 is preferably configured to store the latest known redundant column address identifying an available redundant column spanning redundant planes 43 and 45.

For purposes of illustrating repair of chips having the configuration of FIG. 10, it is once again assumed that the test results are those depicted in FIG. 7. As a result, address register 32 of chip A stores the column 0 address and a fail flag; address register 32 of chip B stores the column 1 address and a fail flag; and the address registers 32 of chips C and D are clear. It is further assumed that an available redundant column spanning planes 43 and 45 is found in chip A and that the column address of that redundant column is stored in the redundancy register 71 of chip A. It is also assumed that an available redundant column is found in chip B and that the column address of that redundant column is stored in the redundancy register 71 of chip B.

It is preferred that the repair of any chip be carried out by replacing the primary memory cells associated with the column address stored in address register 32 with redundant memory cells associated with the redundant column address stored in redundancy register 71. An exemplary set of commands for repairing the chips appears in the table in FIG. 8B. The table in FIG. 8B indicates that instructions may be transmitted to at least the address input ADDR 60, the command input CMD 62, and the DQ input 64 illustrated in the circuitry of FIG. 9. Because it is preferred to repair an entire column, the address inputs need only cycle through the column addresses, with the row addresses having a “don't care” value. Thus, the repair device first transmits the first column address to chips A-D through the address input ADDR 60 and the “blow anti-fuse” command by way of input CMD 62. Concerning the DQ input 64, it may be a “don't care” value or may be used to serve another purpose that would not be available in prior art methods. For instance, it is preferred that the DQ input 64 be used in selecting the anti-fuses to be blown.

Given these inputs, the lack of a fail flag in the registers 32 of chips C and D serves as input to their respective anti-fuse logic circuits 52 and results in ignoring the “blow fuse” command. However, the fail flag bit in the address register 32 of chip A results in a comparison within that chip's anti-fuse logic circuit 52 of the column address input at ADDR 60 and the column address stored in the address register 32. For chip A, that comparison will reveal a match. As a result, chip A's anti-fuse logic circuit 52 will cause the anti-fuses associated with the data in the redundancy register 71 to blow. In this example, two redundant elements will be accessed, one in each redundant plane 43 and 45. For instance, transistor 58 may be driven for a time sufficient to establish a conductive path from CGND to node 68 and the circuitry connected thereto; and a similar process may occur simultaneously in anti-fuse circuit 54′. Such circuitry will isolate the defective cell formerly associated with the first address and associate a redundant cell with that address. It will also isolate a fully functional cell associated with the third address and associate a redundant cell with that address. It should be noted that, while the simultaneous repair mentioned above is preferred, it is not a requirement of every embodiment of the current invention. For instance, there may be a case wherein limitations in the tester equipment result in blowing the anti-fuses in series.

Chip B also has a fail flag bit in its register and, as a result, may compare the address input at ADDR 60 with the address stored in its own register 32. The comparison, however, will not reveal a match. As a result, the command to blow a fuse will not be carried out in chip B at this point. It should now be appreciated that these functions on chips A-D may be occurring at the same time.

Next, as seen in FIG. 8B, the repair device could transmit the second column address in parallel to chips A-D through the address input ADDR 60, while the input CMD 62 gives the blow command and DQ input 64 may serve at least one of several functions discussed above. Chips C and D may once again ignore the command to blow a fuse due to the lack of a fail flag. Chip A may once again compare the new column address input at ADDR 60 with the column address stored in its register 32. This time, however, the lack of a match will result in no anti-fuse being blown. Chip B may once again compare the new column address input at ADDR 60 with the column address stored in its register 32. This time, however, there will be a match. Thus, chip B's anti-fuse logic circuit 52 will cause the anti-fuses associated with the redundant column stored in chip B's redundancy register 71 to blow. More specifically, chip B's anti-fuse logic circuit 52 will drive transistors 58″ and 58′″ for a time sufficient to establish a conductive path from CGND to nodes 68″ and 68′″ and the circuitry connected thereto. Again, two redundant elements will be accessed, preferably simultaneously (but again, simultaneity is not required), one in each redundant plane 43 and 45. Such circuitry may isolate the defective cell formerly associated with the second address of chip B and associate a redundant cell with that address. Such circuitry may also isolate the effective cell formerly associated with the fourth address of chip B and associate a redundant cell with that address. Again, these functions will occur on each chip A-D at the same time.

The overall result is that this exemplary method embodiment accomplishes in two clock cycles what took the prior art method sixteen clock cycles. Another advantage of this exemplary embodiment is that the chips need not be removed from a tester and placed into a separate repairing device. Rather, the chips may remain in a tester and use its input signals while the on-chip circuitry effects repairs. Thus, it is possible to repair chips in an AMBYX device without moving them to a TERADYNE device.

Further, once the data in redundancy register 71 of any chip is no longer needed, the redundancy register 71 may be cleared in anticipation of a subsequent search for another available redundant column.

In the exemplary embodiments of FIGS. 9A and 10, it can be said that multiple redundant planes “share” a redundant register because the information that may be stored therein is relevant to both of those planes. In these embodiments, the information may be a redundant column address, wherein at least one cell in that redundant column is at least a part of one redundant plane; and at least one other cell, also in that redundant column, is at least a part of another redundant plane.

FIG. 9B illustrates another example that helps illustrate the general preference that there should be a single redundant register for a plurality of redundant planes, wherein each redundant plane of the plurality is configured to accommodate the same column of the main memory array. In FIG. 9B, there is a memory array 14 having sixteen addresses arranged into four columns and four rows. FIG. 9B graphically illustrates that the redundant array 42 is divided into four planes 500, 502, 504, and 506, wherein each plane comprises redundant cells and is configured to replace cells associated with four particular address of the main memory array 14. Redundant plane 500, for example, is configured to provide redundancy for one part of column 0, and redundant plane 504 is configured to provide redundancy for another part of column 0. Hence it is preferred to provide a redundancy register 71 that can store the column address of a redundant column that is available to replace the cells of column 0 of main memory array 14. Redundant plane 500 is also configured to provide redundancy for one part of column 1, and redundant plane 504 is also configured to provide redundancy for another part of column 1. Given the error detect circuitry that is preferred to combine with a “Smart Repair” embodiment, only one column will be repaired during a repair mode, and the redundant column address that may be stored in redundant register 71 would be capable of accommodating either main memory column 0 or 1. As a result, there is no need for an additional redundancy register solely for main memory column 1. Rather, planes 500 and 504 may share redundancy register 71. However, redundancy register 71 may not store a redundant column address capable of accommodating either main memory column 2 or 3. Accordingly, a second redundancy register 73 is provided, and because redundant planes 502 and 506 accommodate portions of columns 2 and 3, those redundant planes 502 and 506 share second redundancy register 73. Thus, should the address register 32 store column 2 or 3 as being the column with the last found defective cell, second redundancy register 73 will indicate if there is a redundant column available for one of those main columns and, if so, which redundant column is available.

From these examples, it can be seen that, where a redundant column is divided among a plurality of redundant planes, it is preferred that there be one redundancy register that may store a column address that is common to all planes of the plurality. However, while such a characteristic is preferred, it is by no means required by every embodiment of the current invention.

It should be noted that other exemplary embodiments fall within the scope of the current invention. For example, it may be possible to have a redundancy register that stores the redundant column address of the first available redundant column found rather than the last. Alternatively, it may be preferred in certain circumstances to store some redundant column address other than the first or the last. In addition, it is not necessary that the address stored be a column address—it could be a row address. Moreover, it is not necessary that the redundancy register store data concerning an address that is common to a plurality of redundant cells. Rather, the redundancy register may store other data indicating the availability of cells unrelated by addresses. For instance, the redundancy register could store a plurality of row and column addresses. Further, it is not required by the current invention to store data indicating the availability of a plurality of cells, as it may be preferable in certain circumstances to store data indicating the availability of only a single redundant cell. It is also not necessary to store an address in the redundancy register, as other information may be stored to indicate the availability of at least one redundant cell. For example, the redundancy register may store data related to the programmable element associated with a redundant element. Furthermore, it is not required for every embodiment of the current invention that a redundancy register be shared between redundant planes, or that the concept of redundant planes be incorporated at all. Instead, the current invention includes within its scope embodiments wherein redundancy registers are provided for each redundant column, as well as embodiments wherein redundancy registers are divided among portions of the redundant array by some way other than redundant planes. Moreover it is not required to include error detection considerations in all embodiments concerning “Smart Repair.” Still other embodiments include those wherein the redundancy register is not limited to being on chip.

B. Speedy Repair

Regardless of whether an exemplary embodiment of the current invention incorporates methods and circuits concerning error detection or the number and relationship of elements used in repair and/or recording the availability of redundant elements, at least some exemplary embodiments of the current invention concern the timing of signals transmitted during repair.

As mentioned briefly above, repairing a chip may involve blowing an anti-fuse, wherein doing so may isolate at least one cell formerly related to an address and associate at least one redundant cell with that address. In order to blow an anti-fuse, such as anti-fuse 56 in FIG. 6, for example, the voltage difference between the conductive elements of anti-fuse 56 must be great enough for long enough to break down the dielectric between those conductive elements. In the current non-limiting example, it has been assumed that parameters sufficient to blow anti-fuse 56 include one conductive element of anti-fuse 56 having a voltage of CGND and the other having a voltage of ground for at least two milliseconds. FIG. 6 illustrates that one conductive element of anti-fuse 56 is coupled to CGND. However, the other conductive element of anti-fuse 56 is in electrical communication with ground only when transistor 58 is on. Thus, transistor 58 should be on for at least two milliseconds in order to blow anti-fuse 56. It follows that the signal output from anti-fuse logic circuit 52 must drive the gate of transistor 58 for at least two milliseconds. In the prior art, that required the signals input to the anti-fuse logic circuit 52 to be maintained for at least two milliseconds—which FIG. 11A represents as the time spanning from t₀ to t₁. FIGS. 11A-C further illustrates a specific example of the prior art input signals and their required timing, wherein the first address and a high DQ signal are transmitted to the anti-fuse logic 52 through the appropriate inputs during the time spanning from t₀ to t₁. Once the address signal or DQ change, the signal to transistor 58 will change soon thereafter. In FIG. 11A, the anti-fuse logic 52 is synchronous with respect to both the address and DQ signals; that is, a change in those signals will not affect the output of the anti-fuse logic 52 until the next rising edge of the clock signal CLK. If one of the signals ADDR or DQ were asynchronous, then the change in output would not wait for the next clock pulse. Rather, given the command timing in FIG. 11A, the signal to transistor 58 would change shortly after time t₁, once the change in ADDR or DQ propagated through the anti-fuse logic 52. Given the time spanned by the address and DQ signals in FIG. 11A, asynchronous signals would persist long enough to blow anti-fuse 56.

It is desirable to reconfigure the input signals as soon as possible in order to have the option to blow the next anti-fuse and generally shorten repair time, but FIG. 11B illustrates what happens if the signals are asynchronous and are changed before time t₁. If either the ADDR or DQ signal change at a time t_{X} before t₁, then the signal driving transistor 58 changes once the change in ADDR or DQ propagate through the anti-fuse logic 52—too soon to ensure a complete blowing of anti-fuse 56. Even if the signals were synchronous, there might be a delayed effect from changing ADDR or DQ given that the results of the change will not be effective until the next clock pulse. Nevertheless, as shown in FIG. 11C, that delay may still be insufficient.

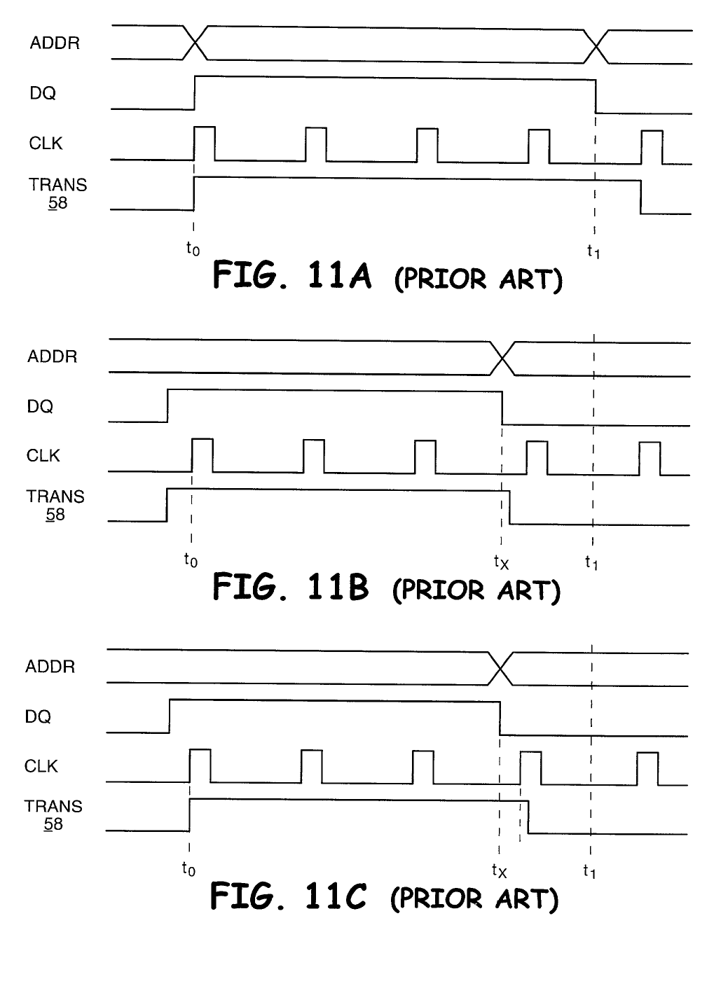

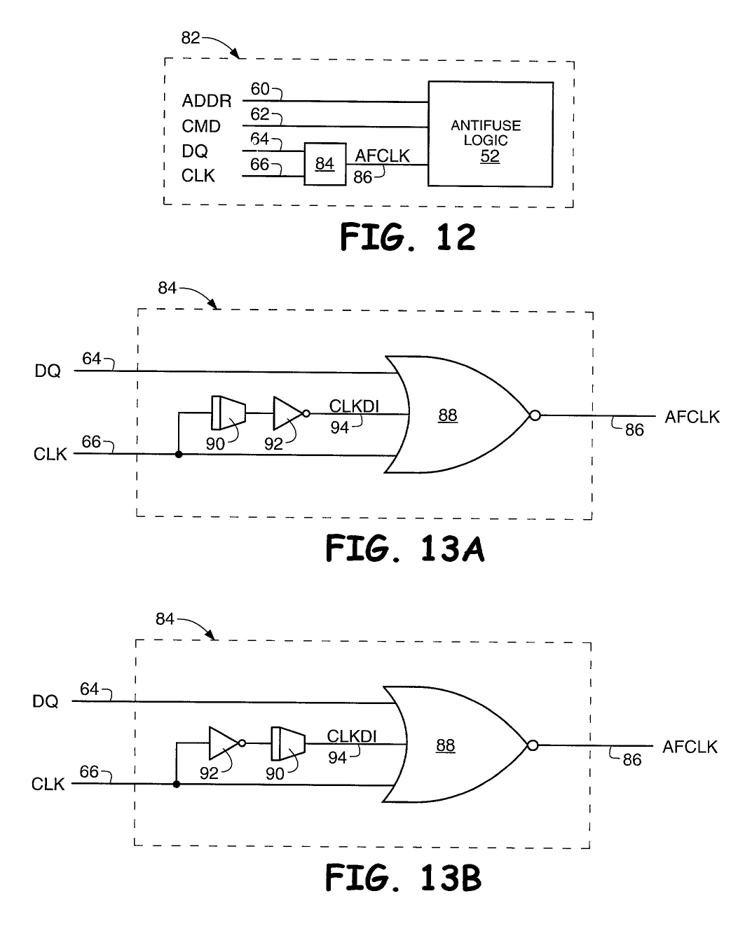

At least some exemplary embodiments of the current invention offer an alternative to the repair schemes of the prior art. For example, in FIG. 12's circuitry included as part of a chip 82, the signals DQ 64 and CLK 66 are intercepted before being input to the synchronous anti-fuse logic 52 and instead undergo logic operations within an anti-fuse clock circuit 84. The result is an anti-fuse clock signal AFCLK 86 that governs the synchronous functions of anti-fuse logic 52. In at least one exemplary embodiment of the current invention, anti-fuse clock signal AFCLK 86 may allow reconfiguring input signals before the critical time t₁ yet may help to ensure complete blowing of the anti-fuse operated upon before the signal reconfiguration. One example of anti-fuse clock circuit 84 appears in FIG. 13A, wherein signals DQ 64 and CLK 66 serve as two of three inputs for a NOR gate 88. The third input, CLKDI 94, is the result of having sent the clock signal CLK 66 through a delay element 90 and an inverter 92. (In an alternate exemplary embodiment depicted in FIG. 13B, the delay element 90 and inverter 92 are switched.) Given the truth table associated with the NOR logic operation, the only time the output AFCLK 86 transmits a high voltage signal is in response to DQ 64, CLK 66, and CLKDI 94 transmitting low voltage signal at the same time. The anti-fuse logic 52 is configured to react to input signal changes after a change in the anti-fuse clock signal AFCLK 86 rather than a change in the clock signal CLK 66.

An example of this is illustrated in FIG. 14, which displays the same address, DQ, and clock signals as FIGS. 11B and 11C. As in FIGS. 11B and 11C, the address and clock signals, while beginning before to, also end before t₁, a circumstance which risks an incomplete blowing of the relevant anti-fuse in the prior art. FIG. 14, however, also shows that the delay element 90 can be configured such that, even though the address signal ADDR 60 and/or the DQ 64 are changed at a time t_{X} before time t₁, the circumstance of DQ 64, CLK 66, and CLKDI 94 being low at the same time does not occur until after t₁. As a result, there will be no AFCLK 86 pulse between t_{X} and t₁. Rather, the relevant clock pulse of AFCLK 86 will not occur until after t₁. Thus, a second address may be transmitted in parallel to multiple chips having the configuration of FIG. 12 and/or the DQ's transmitted to each such chip may be altered based on what is preferred for the second address, yet each chip will continue to internally maintain the signals necessary to blow the anti-fuse associated with the first address.

Exemplary embodiments of the current invention addressing the timing of input signals transmitted during repair may be used in conjunction with input signals wherein the DQ signal determines whether the command to blow an anti-fuse is ignored or where the DQ signal may have alternative effects, such determining which fuses are to be used. Moreover, exemplary embodiments of the current invention addressing the timing of input signals for repair may be used with or without the error detect or “Smart Repair” features discussed above.

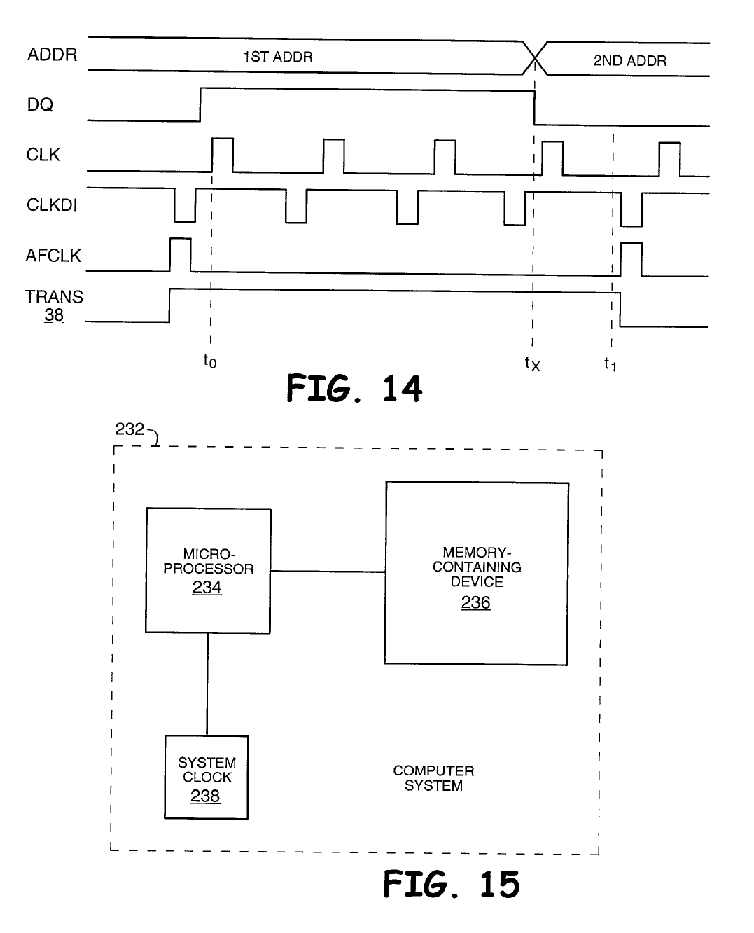

Further, exemplary embodiments of the current invention, be they ones addressing error detection, smart repair, speedy repair, or combinations thereof, generally accommodate systems using memory, wherein the memory can include nonvolatile, static, or dynamic memory, and wherein the memory can be a discrete device, embedded in a chip with logic, or combined with other components to form a system on a chip. For example, FIG. 15 illustrates a computer system 232, wherein a microprocessor 234 transmits address, data, and control signals to a memory-containing device 236 such as one including but not limited to those described above. A system clock circuit 238 provides timing signals for the microprocessor 234.

One skilled in the art can appreciate that, although specific embodiments of this invention have been described above for purposes of illustration, various modifications may be made without departing from the spirit and scope of the invention. For example, the error detection or repair methods described above may occur at any stage of die singulation, including but not limited to states in which the chip's die is part of a wafer, integral with at least one other die yet separate from a wafer, or completely singulated from all other die. Further, the error detection or repair methods may occur at any stage of packaging, ranging from a bare die to a fully packaged chip, although it is preferred to carry out testing and repair methods of the current invention with a fully packaged chip. Error detection or repair methods can occur on any device capable of handling the chip based on its state of singulation or packaging, including AMBYX and TERADYNE devices. Error detection or repair methods can occur during a test, probe, or burn-in (including cold burn-in) process.

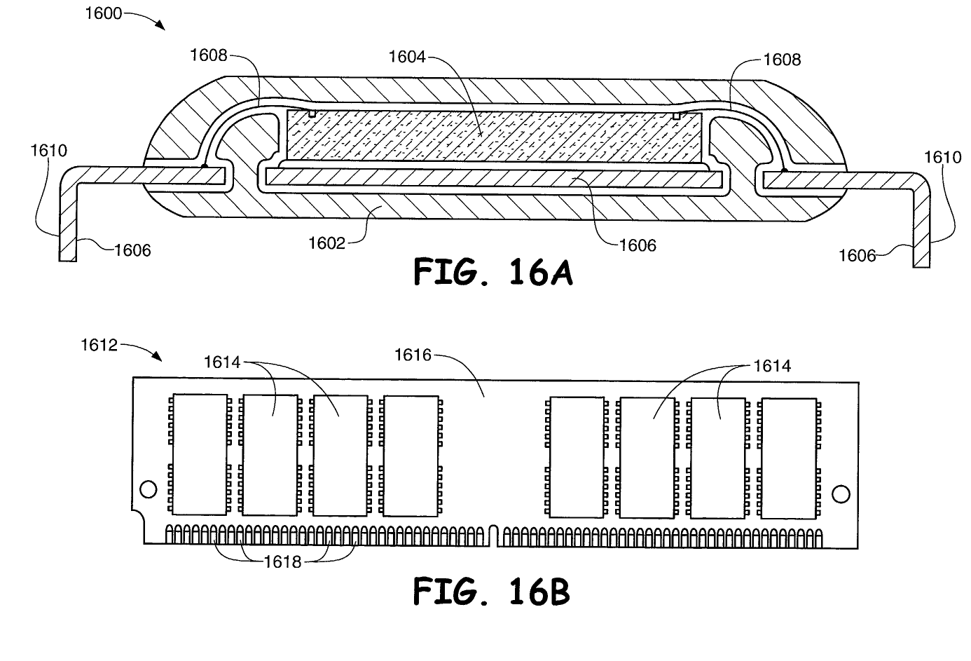

Moreover, the error detection or repair described above may occur at even later stages in at least one exemplary embodiment of the current invention. For example, error detection or repair may occur once a die is “in the field,” wherein the die is out of the die-producer's control. Such circumstances may include those wherein the die has been incorporated as part of an electronic system for an indefinite period of time. Incorporation may involve a single die in a package such as the package 1600 seen in FIG. 16A, wherein encapsulant 1602 protects a die 1604 that is mounted on a lead frame 1606, and wires 1608 are bonded to the die 1604 and lead fingers 1610 of the lead frame 1606. Other packages that may be relevant to exemplary embodiments of the current invention include, but are not limited to, flip chip packages, chip scale packages, ball grid array (BGA) packages, land grid array (LGA) packages, pin grid array (PGA) packages, dual in-line packages (DIP), zig-zag in-line (ZIP) packages, leadless chip carrier (LCC) packages, small outline packages (SOP), thin small outline packages (TSOP), quad flat pack (QFP) packages, and small outline j-bend (SOJ) packages.

Alternatively, error detection or repair may occur on a die that is packaged as part of a multi-chip module 1612, as seen in FIG. 16B, wherein a plurality of die 1614 are mounted onto a support surface such as a printed circuit board 1616. The die 1614 may be linked by conductive traces (not shown) in or on the board 1616. At least some of these traces connect with conductive contacts 1618 in one or more rows along at least one edge of the board 1616.

Moreover, combinations of the packages described above are included within the scope of the invention, one example being a flip chip on module (FCOM), wherein flip chips are bonded to a common substrate such as a printed circuit board.

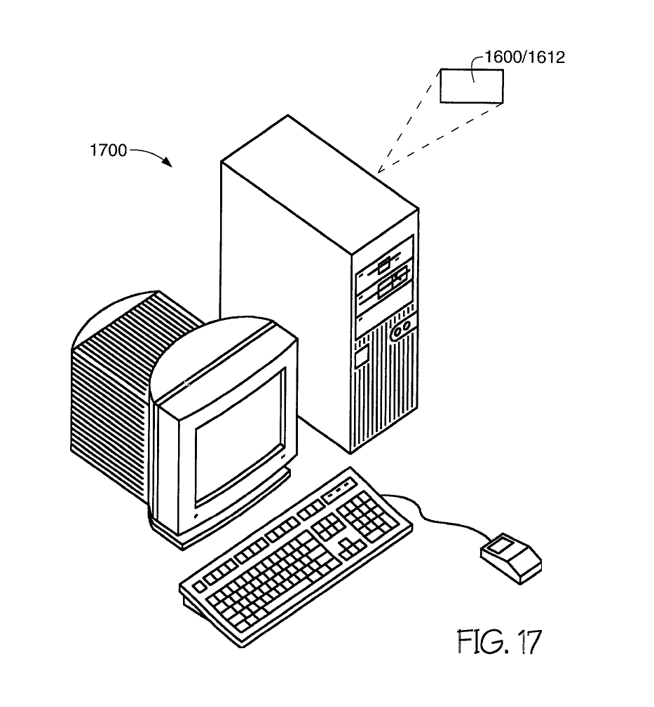

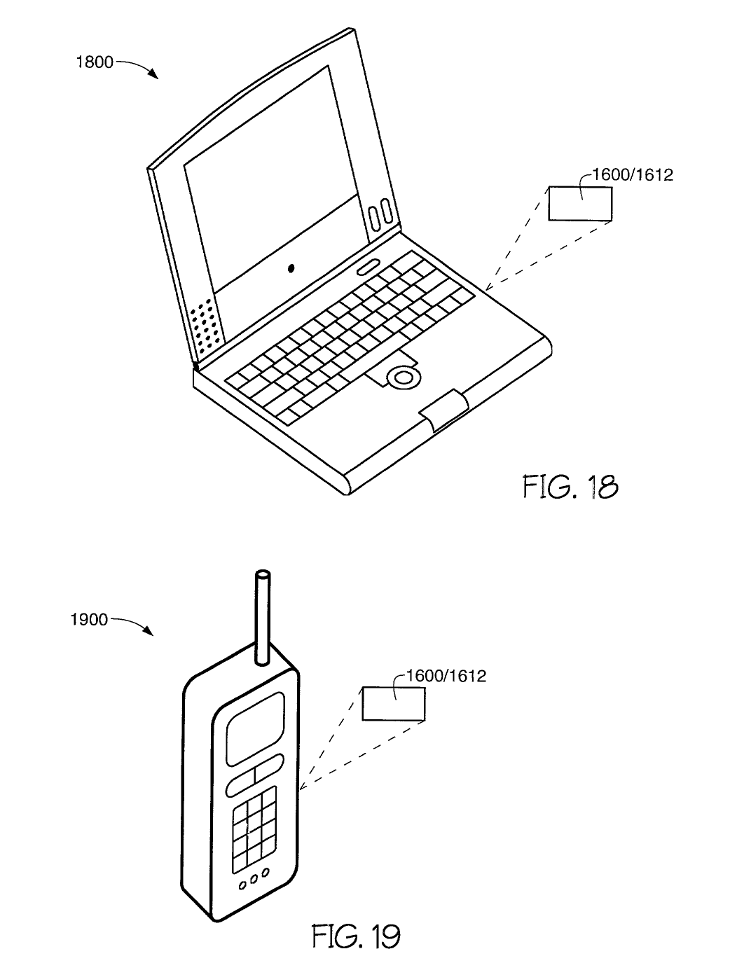

Exemplary electronic systems that are “in the field” and incorporate any of the packages described above, as well as alternative packages, may include a computer system such as a desktop computing system 1700 (FIG. 17) or a laptop computing system 1800 (FIG. 18). “In the field” circumstances also include those wherein the die is part of an electronic system such as a cellular phone 1900 (FIG. 19), where again the die could be packaged singly or with other die in a module. Moreover, “in the field” circumstances include those wherein the die is part of a system that is a combination or hybrid of the systems described above as well as others.

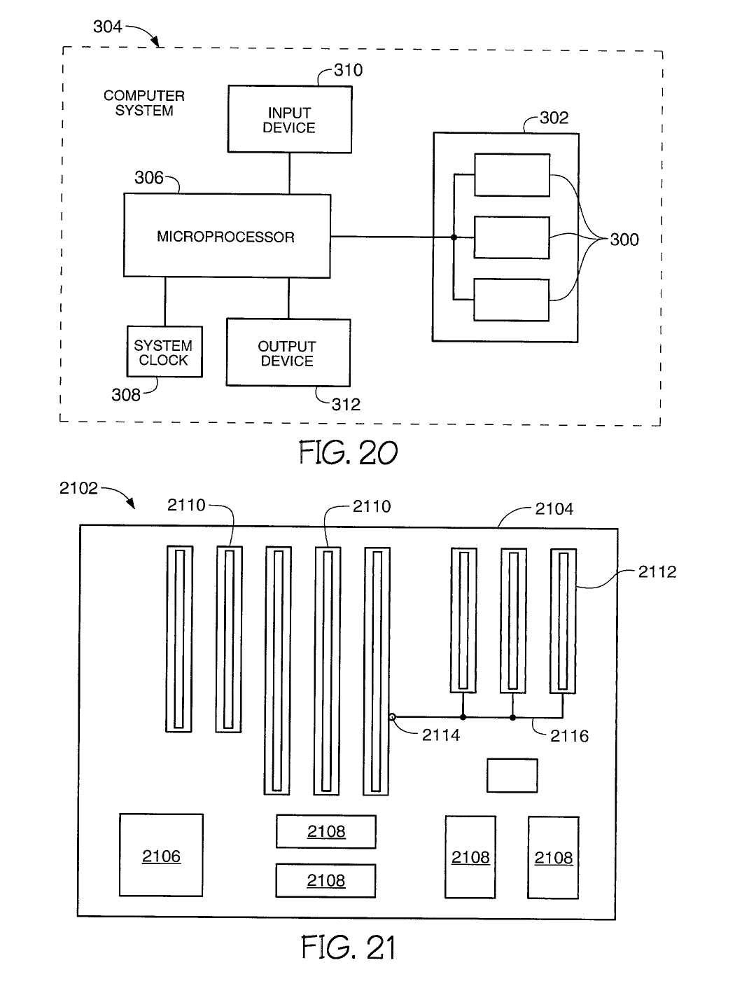

Focusing on error detection under such circumstances, it follows that the test signals sent to the chip need not originate from a device devoted primarily to testing, such as the AMBYX tester. Rather, they may be transmitted from a larger system incorporating the chip, such as the systems described above. In a preferred embodiment of this type, depicted in FIG. 20, several chips 300 are part of a memory module 302, which is in turn a part of a computer system 304. An embodiment wherein several chips 300 are in a module 302 is preferred because, as with testing chips in a tester, signals may be transmitted to the module's chips 300 in parallel. Computer system 304 further comprises a microprocessor 306, which transmits addresses, data, and control signals to the module 302; a system clock 308 which provides timing signals for the microprocessor 306; at least one input device 310, which may include a keyboard, mouse, joystick, touchpad, microphone, video camera, modem, etc.; and least one output device 312 which may include a monitor, speaker, printer, modem, or virtual-reality goggles.

Error detection may be initiated by signals from at least one input device 310. Such a configuration of the computer system is preferred because it would allow one to initiate error detection when desired. It is additionally preferred that the microprocessor 306 be configured to initiate error detection as well. This configuration of the computer system is even more preferred because it would allow error detection while the computer system is in a power management mode, such as a “sleep mode,” wherein power to and/or activity of at least one of the system's components is lessened. Such a configuration also allows the microprocessor 306 to initiate error detection after an input device 310 has not transmitted a signal for an amount of time, analogous to the way a computer system's screen saver program may be initiated. In this exemplary embodiment, the microprocessor 306 writes test data to the chips 300 and maintains transmission of this data while the chips 300 are in a read mode. The results may be stored in an on-chip register as discussed above in part I.

Regardless of how error detection is initiated or carried out in the field, the results of the error detection may be addressed by updating the computer system's Basic Input Output System (BIOS). BIOS is a sequence of instructions which may be stored in read-only memory (ROM). The BOIS instructions concern power-up, self-test, and communication between components on the computer system's motherboard, among other functions. Obtaining an updated BIOS may occur in several ways. For example, the results of the error detection may be transmitted to at least one output device 312 of the computer system 304, and in response one may use an input device 310 to instruct the computer system 304 to access the internet and download the BIOS update from an appropriate internet site. As another example, just as error detection may be performed automatically by the microprocessor 306, so too may the downloading process be automatic, with the microprocessor 306 contacting the internet site and downloading the BOIS update without receiving a particular signal from an input device 310. This alternative may occur in a power management mode as discussed above. Still another alternative within the scope of the invention involves transferring the BIOS update to the computer system 304 from a mobile storage device such as a floppy disk, CD-ROM, or DVD-ROM.

It is preferred that the updated BIOS contain a set of instructions that allow for blowing at least one anti-fuse on at least one chip 300 identified as having a defective memory cell. It is further preferred that the set of instructions also be able to return the chip 300 to a normal state of operations and, in an even more preferable embodiment, provide some sort of flag or indication via an output device 312 that an error has been found and repaired.

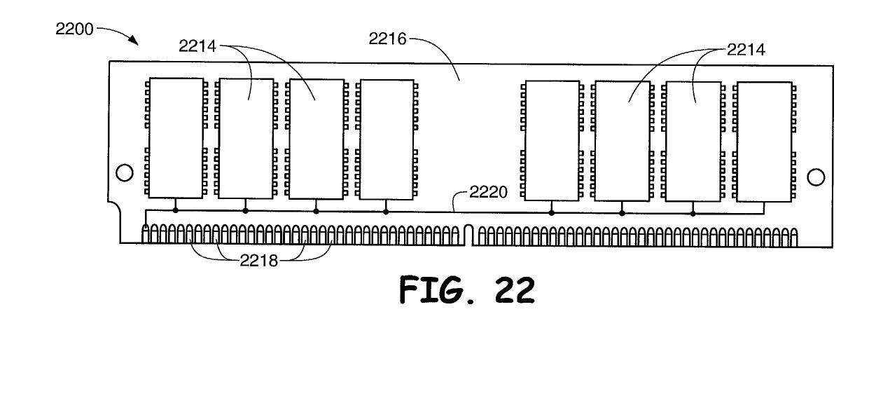

Concerning error repair embodiments relevant to these circumstances, it follows that the repair signals sent to the chip 300 need not originate from a device devoted primarily to repairing, such as a TERADYNE device. Maintaining the computer system example discussed above, it is preferred to allow the chip 300 within that system 304 to carry a voltage source sufficient to blow the anti-fuse. In many computer system configurations, the die is coupled to a motherboard which carries such a voltage. FIG. 21 illustrates a motherboard, 2102, comprising a dielectric substrate 2104. The substrate 2104 is configured to accommodate various components including a central processing unit (CPU) 2106, various semiconductor devices 2108, input/output connections such as expansion slots 2110, which may include peripheral component interconnect (PCI) slots, industry standard architecture (ISA) slots, and accelerated graphics port (AGP) slots. The expansion slots 2110 allow for communication with various input or output devices, such as the ones discussed above in connection with FIG. 20. Also connected to the motherboard are memory sockets 2112 configured to receive memory devices such as the ones in FIGS. 16A or 16B. At some point on the motherboard 2102 (perhaps at an expansion slot 2110) is a terminal 2114 configured to carry a twelve-volt signal. Such voltage may be used on the motherboard 2102 to accommodate an ADD converter, a disk drive, a universal serial bus (USB) connection, and/or flash memory. Accordingly, the motherboard 2102 also comprises conductive lines configured to provide that voltage where desired. Most of the conductive lines are not shown in FIG. 21 to avoid unduly complicating that figure. Such voltage may also be used for repair in exemplary embodiments in the current invention; and FIG. 21 does illustrate a conductive line 2116 extending from the terminal 2114 to the memory sockets 2116 to allow such repair. On-chip error repair is further facilitated by circuitry added to the memory device configured to fit in the socket of the motherboard. FIG. 22 illustrates a multi-chip module 2200. Like the module 1612 in FIG. 16B, module 2200 comprises a plurality of die 2214 mounted onto a support surface such as a printed circuit board 2216. The die 2214 may be linked by conductive traces (not shown) in or on the board 2216. At least some of these traces connect with conductive contacts 2218 in one or more rows along at least one edge of the board 2216. Further, at least one of these traces 2220 is configured to electrically communicate through a contact 2218 with conductive line 2216 on the motherboard and hence carry the twelve-volt signal to the die 2214. That contact 2218 could be what would be designated as a “no-connect” pin in prior art packages.

As a result, sufficient voltage is carried to the device via the motherboard to allow for on-chip error repair as discussed in part II above while a memory device is in the field and/or part of an electronic device such as a computer system. Moreover, as with the testing and software download stages discussed above, error repair may occur while the system is in a power management mode. Further, the results of the repair may be transmitted to an output device 312 of the computer system 304.

Thus, these embodiments concerning error detection and repair “in the field” further demonstrate that the current invention addresses all stages of die singulation, packaging, and incorporation with other electronics. These embodiments further demonstrate that the current invention addresses all sources of error detection or repair signals, be they from a device devoted primarily to repair, devoted primarily to test, or merely capable of test and repair in addition to other functions. These embodiments also demonstrate that the current invention addresses any package or end-user application.

Concerning the function in at least some exemplary embodiments of storing a single address, it is not required under all exemplary embodiments of the current invention to store the last address. Rather, the current invention includes within its scope embodiments wherein the first failed address and only the first address (if any) is stored. Moreover, at least some error detection or repair methods of the current invention may be used in either compression or non-compression data transfer test modes. Accordingly, the invention is not limited except as stated in the claims.

What is claimed is:

1. A method of testing a memory die, comprising:
allowing said memory die to be placed in a location outside of a production facility of said die;
testing said memory die while said die is in said location; and
storing a partial memory cell address on said die as a result of said testing act, wherein said address corresponds to a memory cell having failed said testing act.

2. The method in claim 1, wherein said testing act comprises testing said die while said die is part of an electronic system.

3. The method in claim 2, wherein said testing act comprises testing said die while said electronic system is in a power management mode.

4. The method in claim 2, wherein said testing act comprises testing said die while said die is part of a computer system.

5. The method in claim 2, wherein said testing act comprises testing said die while said die is part of a telephone system.

6. The method in claim 5, wherein said testing act comprises testing said die while said die is part of a cellular telephone system.

7. A method of repairing a memory die, comprising:
reconfiguring an electrical communication path within said memory die subsequent to:
removing said memory die from a production facility for said die, and
incorporating said die as part of an electronic system;
retaining said die as part of as part of said electronic system during said reconfiguring act; and
indefinitely retaining said die as part of as part of said electronic system after said reconfiguring act.

8. The method in claim 7, wherein said reconfiguring act comprises programming a programmable element.

9. The method in claim 8, further comprising transmitting a result of said reconfiguring act to an output device of said electronic system.

10. A method of processing a plurality of memory circuits, comprising:
incorporating said plurality of memory circuits into an electronic system, said system having a primary function other than test or repair of said plurality of memory circuits; and
transmitting a signal in parallel to said plurality of memory circuits, said signal relating to a selection consisting of simultaneously testing said plurality of memory circuits and simultaneously repairing said plurality of memory circuits, said transmitting act occurring while said plurality of memory circuits are incorporated into said electronic system.

11. The method in claim 10, wherein said transmitting act comprises transmitting a signal in parallel to a plurality of die, wherein each die of said plurality of die comprises at least one memory circuit.

12. The method in claim 11, wherein said transmitting act comprises transmitting a signal to a module comprising said plurality of die.

13. A method of processing a memory die, comprising:
incorporating said memory die into an electronic system for an indefinite amount of time; and
physically rerouting an electrical communication path of said die while said die is part of said electronic system.

14. The method in claim 13, wherein:
said incorporating act comprises incorporating said die into an electronic system comprising control circuitry and an input device coupled to said control circuitry; and
said rerouting act comprises rerouting in response to said control circuitry receiving a signal from said input device.

15. The method in claim 13, wherein said
said incorporating act comprises incorporating said die into an electronic system comprising control circuitry and at least one input device coupled to said control circuitry; and
said rerouting act comprises rerouting in response to said control circuitry receiving no signal from any input device for a span of time.

16. The method in claim 13, wherein:
said incorporating act comprises incorporating said die into an electronic system comprising control circuitry; and
said rerouting act comprises initiating rerouting with said control circuitry.

17. The method in claim 13, further comprising adding rerouting software to said electronic system before said rerouting act.

18. The method in claim 17, wherein said act of adding rerouting software comprises downloading said software from an internet site into said electronic system.

19. The method in claim 18, wherein said downloading act comprises downloading a BIOS update comprising at least one instruction concerning programming at least one element on said memory die.

20. The method in claim 19, wherein said act of rerouting comprises transmitting a signal to said memory die from another component of said electronic system, wherein said signal is configured to program at least one element on said memory die.

21. The method in claim 20, wherein said act of rerouting comprises programming at least one element on said memory die.

22. The method in claim 21, wherein said act of rerouting comprises allowing said memory die access to a voltage sufficient to program at least one element on said memory die.

23. A method of operating an electronic system including memory, comprising:
initiating a power management mode of said electronic system;
testing said memory while said electronic system is in said power management mode; and
storing at most a partial result of said testing act within said electronic system.

24. The method in claim 23, further comprising downloading instructions into said electronic system while said electronic system is in said power management mode.

25. The method in claim 24, further comprising physically repairing said memory while said electronic system is in said power management mode.

26. A method of operating memory, comprising:
indefinitely incorporating said memory into a computer system; and
initiating a memory test while said memory is part of said computer system, wherein said memory test comprises:
writing a data pattern from a microprocessor of said computer system to said memory,
continuing to transmit said data pattern from said microprocessor to said memory during a read mode of said memory,
comparing data stored on said memory as a result of said writing act with said data pattern transmitted during said read mode, and
storing less than a full address from said memory as a result of said memory test.

27. The method in claim 26, wherein said storing act occurs in a storage device sharing a common substrate with said memory.

28. The method in claim 26, wherein said initiating act comprises receiving a signal from an input device of said computer system.

29. The method in claim 26, wherein said initiating act comprises transmitting a signal from said microprocessor.

30. The method in claim 26, further comprising transmitting a signal to an output device of said computer system, wherein said transmitting act occurs in response to said result.

31. The method in claim 26, further comprising obtaining memory repair instructions, wherein said obtaining act occurs in response to said result.

32. The method in claim 26, further comprising supplying a voltage to said memory in response to said result, wherein said voltage has a magnitude sufficient to affect any unprogrammed element on said memory.

33. A method of preparing a memory circuit for an alteration of its configuration, comprising:
providing a plurality of memory elements which define a plurality of redundant planes, wherein each memory element of said plurality of memory elements has an address;
incorporating said memory circuit into an electronic system for an indefinite amount of time; and
searching for particular memory elements from said plurality of memory elements, wherein said particular memory elements are isolated from input and output terminals of said memory circuit, wherein said particular memory elements share a partial address, wherein said partial address is relevant to at least two redundant planes, and wherein said searching act occurs subsequent to said incorporating act.

34. The method in claim 33, further comprising storing at most said partial address in a storage device.

35. The method in claim 34, wherein said storing act comprises storing at most said partial address in a storage device, wherein said storage device shares a common support surface with said memory circuit.

36. The method in claim 34, wherein said storing act comprises storing at most said partial address in a storage device, wherein said storage device is configured to hold an amount of data corresponding to at most that of said partial address.

37. A method of in-field programming of an electronic circuit on a chip, comprising:
incorporating said electronic circuit into a computer system for an indefinite period of time;
generating a plurality of signals, an effect of which is configured to program an element within said circuit, wherein said generating act occurs external to said chip, and wherein said generating act occurs while said electronic circuit is part of said computer system;
altering at least one of said plurality of signals, wherein said altering act occurs external to said chip; and
maintaining said effect despite said altering act, wherein said maintaining act occurs internal to said chip.

38. The method in claim 37, wherein said maintaining act comprises maintaining said effect for a time sufficient to program said element.

39. The method in claim 38, wherein said altering act occurs while said electronic circuit is part of said computer system.

40. The method in claim 39, wherein said maintaining act occurs while said electronic circuit is part of said computer system.

41. An electronic system, comprising:
control circuitry;
at least one input device coupled to said control circuitry;
at least one output device coupled to said control circuitry; and
a memory device coupled to said control circuitry and comprising:
at least one memory cell, and
a register configured to hold less than a full address of at most one memory cell at a time.

42. The electronic system of claim 41, wherein said control circuitry, said at least one input device, said at least one output device, and said memory device define a computer system.

43. The electronic system of claim 41, wherein said control circuitry, said at least one input device, said at least one output device, and said memory device define a telephone system.

44. The electronic system of claim 41, wherein said memory device is part of a package.

45. The electronic system of claim 44, wherein said memory device is part of a single-die package.

46. The electronic system of claim 44, wherein said memory device is part of a multi-chip module.

47. A memory package, comprising:
at least one semiconductor die, each of said at least one semiconductor die comprising:
at least one memory cell, and
a register sized to store less than a full memory cell address; and
passivation material covering at least a portion of each of said at least one semiconductor die.

48. The memory package in claim 47, wherein said at least one semiconductor die comprises a single die; and said package further comprises a lead frame coupled to said single die and extending beyond said passivation material.

49. A memory module, comprising:
a support surface;
a plurality of memory die mounted to said support surface, wherein each die of said plurality includes at least one program element; and
a trace coupled to said support surface and to said plurality of memory die, wherein said trace is configured to carry signal sufficient to blow any unprogrammed program element on any of said plurality of memory die.

50. The memory module of claim 49, further comprising a conductive contact coupled to said support surface, coupled to said trace, and configured to electrically communicate with an external device.

51. The memory module of claim 49, wherein at least one memory die of said plurality includes a first storage device configured to store data relating to existence of a failed memory cell and at most a part of an address of said failed cell.

52. The memory module of claim 51, wherein at least one memory die of said plurality includes a second storage device configured to store data relating to at most a part of an address of a redundant cell.

53. A motherboard, comprising:
an electrically insulative substrate;
a terminal on said substrate configured to carry a programming voltage; and
a socket coupled to said terminal and configured to receive a memory device.

54. The motherboard in claim 53, further comprising an input/output connection coupled to said terminal.
